(19) United States
(12) Patent Application Publication
(10) Pub. No.: US 2010/0327353 A1
(43) Pub. Date: Dec. 30, 2010

(54) SEMICONDUCTOR DEVICE AND METHOD FOR MANUFACTURING THE SAME

(76) Inventors: Atsushi Shoji, Osaka (JP); Isao Nakanishi, Osaka (JP); Kazushige Hotta, Osaka (JP)

Correspondence Address: NIXON & VANDERHYE, PC, 901 NORTH GLEBE ROAD, 11TH FLOOR, ARLINGTON, VA, 22203, US

(21) Appl. No.: 12/864,955

(22) PCT Filed: Jan. 20, 2009
(86) PCT No.: PCT/JP2009/000169

§ 371 Date: Jul. 28, 2010

(30) Foreign Application Priority Data
Jan. 29, 2008 (JP) 2008-018194

(51) Int. Cl. H01L 29/786

(52) U.S. Cl. 257/347; 257/E29.273

(57) ABSTRACT

A gate electrode 14 of a thin film transistor 100 included in a semiconductor device of the present invention is constituted of a single conductive film. A semiconductor layer 10 includes a first lightly doped impurity region which is provided between the channel region 12 and the source region 15 and which has a lower impurity concentration than those of the source and drain regions 15, and a second lightly doped impurity region which is provided between the channel region 12 and the drain region 15 and which has a lower impurity concentration than those of the source and drain regions 15. The entirety of one of the first and second lightly doped impurity regions (region 16a) extends under the gate electrode, and the other of the first and second lightly doped impurity regions (region 16b) does not extend under the gate electrode.

### TECHNICAL FIELD

The present invention relates to a semiconductor device and a fabrication method thereof.

### BACKGROUND ART

In recent years, liquid crystal display devices have been used in a wide variety of applications because of their advantages, such as light weight, slim appearance, low power consumption, etc. In particular, when an active matrix type liquid crystal display device is used, the number of pixels can be increased, and the contrast ratio in display can be improved, as compared with a passive matrix type liquid crystal display device. Thus, high quality display is possible.

The active matrix type liquid crystal display device has a switching element, such as a thin film transistor (hereinafter, “TFT”), in each pixel. In this specification, a substrate which includes switching elements is referred to as an “active matrix substrate”. A typical active matrix liquid crystal display device includes an active matrix substrate, a counter substrate, and a liquid crystal layer interposed between these substrates. The active matrix substrate includes pixel electrodes in respective ones of the pixels each of which is defined as the unit of display of images. Each of the pixel electrodes is coupled to a corresponding one of switching elements that correspond to the pixel electrodes. Display is performed by controlling the ON/OFF of the switching elements coupled to the respective pixel electrodes to vary the voltage that is applied across the liquid crystal layer via the pixel electrode and a counter electrode provided in the counter substrate. In the active matrix substrate, various functional circuits, such as a driving circuit, can be provided. The TFTs are also used in such a functional circuit. In this specification, a TFT provided in each pixel is referred to as “pixel TFT”, and a TFT used in a functional circuit, such as a driving circuit, is referred to as “driving circuit TFT”.

The pixel TFT is required to provide an extremely small OFF leakage current. In the liquid crystal display device, the voltage applied across the liquid crystal need to be maintained during one frame period prior to rewriting of the screen. If the OFF current (OFF leakage current) of the pixel TFT is large, there is a probability that the voltage applied across the liquid crystal decreases with time, deteriorating the display characteristics.

A structure of the pixel TFT is known in which, for example, at least one of regions between the channel region and the source and drain regions of the TFT is a lightly doped impurity region (Lightly Doped Drain: hereinafter sometimes abbreviated as “LDD region”). Such a structure is called “LDD structure”. Due to the LDD region, the electric field concentration in the vicinity of the drain can be relaxed, so that the OFF leakage current can be greatly reduced as compared with a TFT which does not have a LDD region (“single drain structure”). On the other hand, the LDD region serves as a resistance, so that the current drivability is disadvantageously lower than that of the TFT of the single drain structure.

On the other hand, the driving circuit TFT need to perform a high speed operation and is therefore required to have a large current drivability, i.e., a large ON current.

Therefore, the driving circuit TFT preferably has a different structure from that of the above-described pixel TFT. A structure of the driving circuit TFT is known in which, for example, a LDD region is overlapped by a gate electrode. Such a structure is called “GOLD (Gate Overlapped LDD) structure”. In a TFT which has the GOLD structure, when a voltage is applied to the gate electrode, electrons which serve as carrier are accumulated in part of the LDD region overlapped by the gate electrode. Thus, the resistance of the LDD region can be decreased, and therefore, the decrease of the current drivability of the TFT can be prevented.

The TFT of the GOLD structure has a disadvantage that the OFF leakage current is larger than in the TFT of the above-described LDD structure (a structure where the gate electrode does not extend over the LDD region), and is therefore not suitable to the pixel TFT. This may be because, even when the TFT is in the OFF state, an accumulation layer is formed in part of the LDD region overlapped by the gate electrode. In the GOLD structure, the gate electrode extends over the LDD region, so that the parasitic capacitances between the gate electrode and the source and drain electrodes (Cgs, Cgd) are relatively large. Therefore, it is necessary to increase the gate capacitance. However, increasing the gate capacitance leads to an increase in load capacitance during the operation in a circuit which includes this TFT, and therefore, there is a probability that it adversely affects the circuit operation. This adverse effect is especially large when the channel length of the TFT is short.

Thus, in the conventional TFT structure, it is difficult to decrease the OFF current while increasing the ON current. Therefore, it is necessary to select an optimum TFT structure depending on the use and purpose of the TFT. As such, fabrication of an active matrix substrate which includes an integrated driving circuit requires formation of a pixel TFT and a driving circuit TFT having different structures on the same substrate, resulting in a complicated manufacturing process.

To overcome this disadvantage, Patent Document 1 and Patent Document 2 propose structures that are configured for the purpose of improving the TFT characteristics, in which only part of the LDD region is overlapped by the gate electrode. For example, Patent Document 1 discloses a TFT structure in which a LDD region that is entirely overlapped by the gate electrode (i.e., a LDD region extending under the gate electrode) and a LDD region that is partially overlapped by the gate electrode are respectively provided between the source and drain regions and the channel region.

On the other hand, a TFT structure is proposed in which the gate electrode has a two layer structure constituted of a main-gate electrode and a sub-gate electrode. Patent Document 3 and Patent Document 4 disclose TFT structures in which a sub-gate electrode is provided on a main-gate electrode with an insulating film interposed therebetween, the sub-gate electrode having an equal potential to that of the main-gate electrode, and in which only the sub-gate electrode extends over (overlaps) the LDD region. This structure provides a similar effect to that of the GOLD structure, i.e., a high current drivability, because the sub-gate electrode overlaps the LDD region. Further, the thickness of the insulating film over the LDD region is greater than the thickness of the gate insulating film over the channel portion because the sub-gate electrode is provided on the main-gate electrode with the insulating film is interposed therebetween. Thus, a similar effect to that of the LDD structure, the capability of decreasing the OFF leakage current, can be obtained.

Patent Document 1: Japanese Laid-Open Patent Publication No. 2006-269808

Patent Document 2: Japanese Laid-Open Patent Publication No. 2006-237528

Patent Document 3: Japanese Laid-Open Patent Publication No. 6-13407

Patent Document 4: Japanese Laid-Open Patent Publication No. 6-310724

Patent Document 5: Japanese Laid-Open Patent Publication No. 2005-93871

### DISCLOSURE OF INVENTION

### Problems to be Solved by the Invention

The TFTs having the above-described structures have disadvantages which are described below.

The present inventor conducted researches and found that, in the TFT structures of Patent Document 1 and Patent Document 2, positioning the gate electrode so as to extend over only part of the LDD region requires increasing the LDD length (the length of the LDD region along the channel direction), which disadvantageously increases the size of the TFT. Further, it is difficult to precisely control the length of part of the LDD region which extends under the gate electrode and the length of part of the LDD region which does not extend under the gate electrode. Also, there is a probability that a TFT having predetermined characteristics cannot be assuredly fabricated.

In the TFT structures disclosed in Patent Documents and 4, the sub-gate electrode is constituted of a third electrode layer that is different from the main-gate electrode or the source and drain electrodes. Therefore, a fabrication process of a TFT which has a structure disclosed in these patent documents is more complicated than the fabrication process of a TFT which has a structure that does not include a sub-gate electrode.

Thus, the TFT structures disclosed in the above-described patent documents lead to complicated manufacturing processes, and result in deteriorated productivity, as compared with the conventional TFTs of the LDD structure and the GOLD structure.

The present invention was conceived in view of the above circumstances. One of the major objects of the present invention is to provide a thin film transistor which is excellent in productivity and which provides a reduced OFF current while securing a high current drivability.

### Means for Solving the Problems

A semiconductor device of the present invention includes a thin film transistor, the thin film transistor including a semiconductor layer which includes a channel region, a source region, and a drain region, the source region and the drain region being provided on opposite sides of the channel region, a gate insulating layer provided on the semiconductor layer, a gate electrode provided on the gate insulating layer, a source electrode electrically connected to the source region, and a drain electrode electrically connected to the drain region, wherein the gate electrode is constituted of a single conductive film, the semiconductor layer includes a first lightly doped impurity region provided between the channel region and the source region, the first lightly doped impurity region having a lower impurity concentration than those of the source region and the drain region, and a second lightly doped impurity region provided between the channel region and the drain region, the second lightly doped impurity region having a lower impurity concentration than those of the source region and the drain region, and an entirety of one of the first and second lightly doped impurity regions extends under the gate electrode, and the other of the first and second lightly doped impurity regions does not extend under the gate electrode.

In a preferred embodiment, the gate electrode has a symmetric shape in a cross section which is parallel to a channel direction of the thin film transistor and which extends along a thickness direction of the gate electrode.

In a preferred embodiment, an end of the one of the first and second lightly doped impurity regions which is opposite to the channel region is aligned with an end of the gate electrode, and an end of the other of the first and second lightly doped impurity regions which is on the channel region side is aligned with the other end of the gate electrode.

Another semiconductor device of the present invention includes a thin film transistor, the thin film transistor including a semiconductor layer which includes first and second channel regions, a first heavily doped impurity region provided on an outer side of the first channel region, a second heavily doped impurity region provided on an outer side of the second channel region, and a third heavily doped impurity region provided between the first and second channel regions, a gate insulating layer provided on the semiconductor layer, first and second gate electrodes which are provided on the gate insulating layer and which are provided over the first and second channel regions, respectively, a first electrode electrically connected to the first heavily doped impurity region, and a second electrode electrically connected to the second heavily doped impurity region, wherein the semiconductor layer further includes first lightly doped impurity regions provided between the first channel region and the first heavily doped impurity region and between the first channel region and the third heavily doped impurity region, the first lightly doped impurity regions having a lower impurity concentration than those of the first, second, and third heavily doped impurity regions, and second lightly doped impurity regions provided between the second channel region and the second heavily doped impurity region and between the second channel region and the third heavily doped impurity region, the second lightly doped impurity regions having a lower impurity concentration than those of the first, second, and third heavily doped impurity regions, and an entirety of each of the first lightly doped impurity regions extends under the first gate electrode, and the second lightly doped impurity regions do not extend under the second gate electrode.

In a preferred embodiment, the first and second gate electrodes are constituted of a single conductive film.

In a preferred embodiment, the first and second gate electrodes have a symmetric shape in a cross section which is parallel to a channel direction of the thin film transistor and which extends along a thickness direction of the gate electrodes.

A fabrication method of the present invention is a method for fabricating a semiconductor device which includes a thin film transistor, the method including the steps of: (a) forming an island-shaped semiconductor layer on a substrate; (b) forming a gate insulating film so as to cover the semiconductor layer; (c) implanting a first impurity ion in part of the semiconductor layer with a first dosage, thereby forming a first impurity ion implanted region so as to be adjacent to an end of part of the semiconductor layer which is to constitute a channel region; (d) forming a gate electrode on the gate insulating film so as to cover the part of the semiconductor layer which is to constitute a channel region and at least part of the first impurity ion implanted region; (e) implanting a second impurity ion in the semiconductor layer with a second dosage using the gate electrode as an implantation mask, thereby forming a second impurity ion implanted region so as to be adjacent to the other end of the part of the semiconductor layer which is to constitute a channel region; (f) forming a mask so as to cover a side surface of the gate electrode on the second impurity ion implanted region side and part of the second impurity ion implanted region; and (g) implanting a third impurity ion in the semiconductor layer using the mask and the gate electrode as implantation masks with a third dosage that is higher than the first and second dosages, thereby forming source and drain regions, such that part of the first impurity ion implanted region which is covered with the gate electrode and in which the third impurity ion is not implanted constitutes a first lightly doped impurity region, and part of the second impurity ion implanted region which is covered with the mask and in which the third impurity ion is not implanted constitutes a second lightly doped impurity region.

### EFFECTS OF THE INVENTION

According to the present invention, the OFF leakage current can be decreased while the current drivability of the thin film transistor is secured. Further, such a thin film transistor can be fabricated using a convenient method, without increasing the number of fabrication steps or the fabrication cost.

Applying the above-described thin film transistor to a driving circuit of a display device is advantageous because the OFF characteristic can be improved as compared with the conventional GOLD-structure TFT, while an ON characteristic sufficient for driving a circuit is secured. Using the above-described thin film transistor for a sampling switch is advantageous because the parasitic capacitances (Cgs, Cgd) can be reduced without decreasing the ON current, and the current consumption can also be reduced.

Further, the above-described thin film transistor is excellent in both ON characteristic and OFF characteristic, and can be suitably used as any of a pixel TFT and a driving circuit TFT of the active matrix type display device. Thus, the fabrication process of the active matrix substrate can be greatly simplified while the display characteristics substantially equal to those of the conventional active matrix substrates are secured.

### BRIEF DESCRIPTION OF DRAWINGS

FIG. 1 A schematic cross-sectional view of a thin film transistor of the first embodiment of the present invention.

FIG. 2 (a) is a schematic cross-sectional view showing an arrangement of a semiconductor layer and a gate electrode of a thin film transistor of a conventional LDD structure. (b) is a graph which illustrates the voltage-current characteristic of the thin film transistor of (a).

FIG. 3 (a) is a schematic cross-sectional view showing an arrangement of a semiconductor layer and a gate electrode of a thin film transistor of a conventional GOLD structure. (b) is a graph which illustrates the voltage-current characteristic of the thin film transistor of (a).

FIG. 4 (a) is a schematic cross-sectional view showing an arrangement of a semiconductor layer and a gate electrode of a thin film transistor of the first embodiment of the present invention. (b) is a graph which illustrates the voltage-current characteristic of the thin film transistor of (a).

FIG. 5 (a) to (g) are cross-sectional views for illustrating a fabrication method of a thin film transistor of the first embodiment of the present invention.

FIG. 6 A schematic cross-sectional view of a thin film transistor of the second embodiment of the present invention.

FIG. 7 (a) to (e) are cross-sectional views for illustrating a fabrication method of a thin film transistor of the second embodiment of the present invention.

FIG. 8 A schematic cross-sectional view of a thin film transistor of the third embodiment of the present invention.

FIG. 9 A diagram for illustrating a structure of an analog full monolithic sampling switch.

### DESCRIPTION OF THE REFERENCE NUMERALS

100, 200, 300 thin film transistor
10 semiconductor layer
11 substrate
12, 12A, 12B channel region
13 gate insulating film
14, 14A, 14B gate electrode
15 source region or drain region
16a, 16b, 16Aa, 16Ab, 16Ba, 16Bb LDD region
15A, 15B, 15C heavily doped impurity region
17 interlayer insulating film
18 contact hole
19 source electrode or drain electrode

### BEST MODE FOR CARRYING OUT THE INVENTION

Hereinafter, embodiments of a semiconductor device of the present invention will be described with reference to the drawings. In this specification, a “semiconductor device” includes a wide variety of devices, including semiconductor elements, such as thin film transistors and the like, as well as substrates on which functional circuits are provided and active matrix substrates, and display devices, such as liquid crystal display devices, organic EL display devices, etc.

### First Embodiment

Hereinafter, a semiconductor device of the first embodiment of the present invention is described with reference to the drawings. The semiconductor device of the present embodiment includes a thin film transistor which is described below.

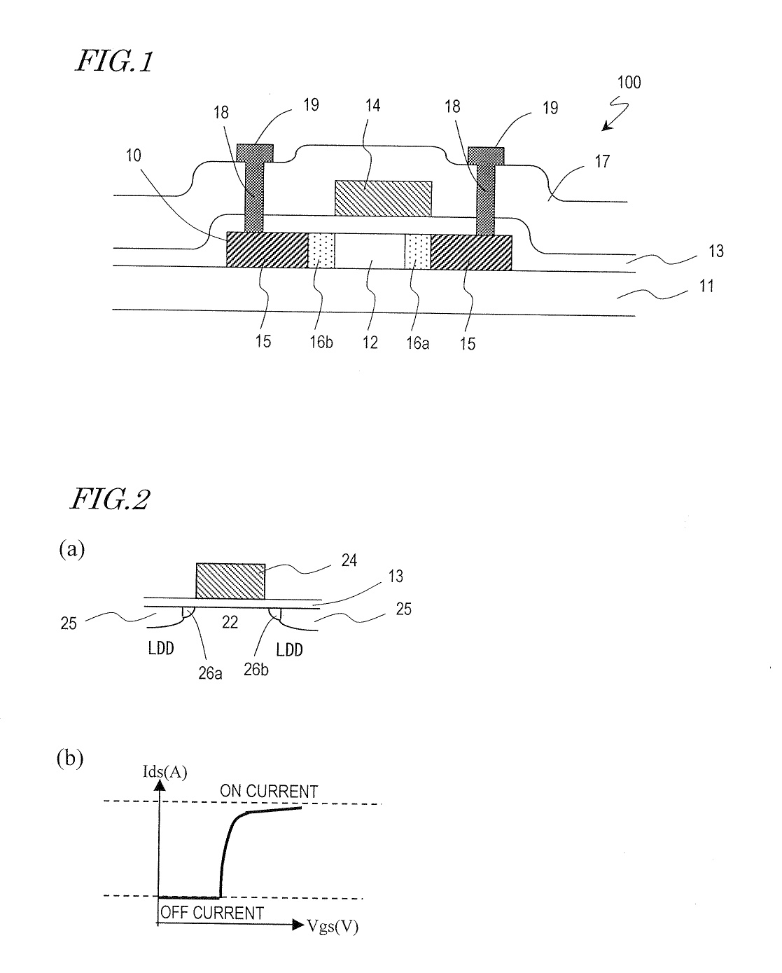

FIG. 1 is a schematic cross-sectional view of a thin film transistor of the present embodiment. The thin film transistor 100 includes a semiconductor layer 10 supported on a substrate 11 that has an insulating surface, a gate electrode 14 which is provided on the semiconductor layer 10 such that a gate insulating film 13 is interposed between the semiconductor layer 10 and the gate electrode 14, an interlayer insulating film 17 which covers the gate electrode 14, and source and drain electrodes 19.

The semiconductor layer 10 includes a channel region 12, source and drain regions (heavily doped impurity regions) 15, and LDD regions (lightly doped impurity regions) 16a, 16b which have a lower impurity concentration than that of the source and drain regions 15. The LDD regions 16a, 16b are respectively provided between the channel region 12 and the source and drain regions 15.

The gate electrode 14 is constituted of a single conductive film. In this specification, the phrase “constituted of a single conductive film” refers to a structure formed by patterning one conductive film (which may be a multilayered film), but does not include a gate structure constituted of two or more conductive films having different patterns, for example, the aforementioned structure constituted of a main-gate electrode and a sub-gate electrode as described in Patent Document 3 and Patent Document 4. Also, the phrase does not include a layered structure constituted of a main-gate electrode and a sub-gate electrode having different patterns without an insulating film interposed therebetween (e.g., Patent Document 5).

In the present embodiment, the gate electrode 14 extends over the entirety of the LDD region 16a (GOLD structure) but does not extend over the LDD region 16b (LDD structure). In this specification, the phrase “the gate electrode extends over the entirety of the LDD region” excludes the case where the gate electrode partially extends over the LDD region. The phrase “the gate electrode does not extend over the LDD region” means that the gate electrode does not extend over any part of the LDD region, and excludes the case where the gate electrode partially extends over the LDD region. Therefore, in this specification, the “GOLD structure” refers to a structure wherein the gate electrode 14 extends over the entirety of the LDD region (herein, the LDD region 16a). On the other hand, the “LDD structure” refers to a structure wherein the gate electrode 14 does not extend over the LDD region (herein, the LDD region 16b). Note that, in the present embodiment, the “LDD region” refers to a region whose impurity concentration is not less than 1×10¹⁷ atoms/cm³ and is lower than the impurity concentration of the source and drain regions 15. Therefore, it does not include a region of the semiconductor layer 10 which contains an impurity at an extremely low concentration (less than 1×10¹⁷ atoms/cm³). For example, it is probable that part of the impurity implanted in the LDD region 16b may be diffused into the channel region 12 that is provided under the gate electrode 14, and however, the impurity concentration of the region into which the impurity is diffused may be estimated to be extremely low. Thus, such a portion is not included in the “LDD region 16b”.

In the present embodiment, the gate electrode 14 may cover only one of the LDD regions 16a, 16b. The gate electrode 14 may cover the LDD region which is on the source side relative to the channel region 12. The gate electrode may cover the LDD region which is on the drain side relative to the channel region 12. Note that the gate electrode 14 preferably covers only the LDD region on the drain side because the reliability of the thin film transistor can be further improved. This is because the electric field relaxation is more necessary on the drain side than on the source side, and the GOLD structure is more resistant to degradation by hot carriers than the LDD structure.

The interlayer insulating film 17 may have a single layer structure or may have a multilayered structure constituted of two or more layers. The interlayer insulating film 17 has contact holes 18 which respectively reach the source and drain regions 15 of the semiconductor layer 10. Conductive layers which are provided on the interlayer insulating film 17 and in the contact holes 18 constitute the source and drain electrodes 19. Thus, the source and drain electrodes 19 are electrically connected respectively to the source and drain regions 15 of the semiconductor layer 10.

In the thin film transistor 100, one of the LDD regions 16a, 16b provided on the source side and the drain side of the channel region 12 has the LDD structure, while the other region has the GOLD structure. Thus, a single unit of the thin film transistor 100 has both the LDD structure and the GOLD structure. The effects produced by such a structure are described below with reference to the drawings.

FIG. 2 to FIG. 4 respectively show the structures and the voltage-current characteristics of a conventional LDD-structure TFT, a conventional GOLD-structure'TFT, and the thin film transistor 100 of the present embodiment. In each of FIG. 2 to FIG. 4, (a) is a schematic cross-sectional view of the thin film transistor which shows the arrangement of the semiconductor layer and the gate electrode, and (b) is a graph that illustrates the voltage-current characteristic of the thin film transistor. For the sake of simplicity, components that are the same as those of FIG. 1 are indicated by the same reference numerals, and the descriptions thereof are herein omitted.

In the conventional LDD-structure TFT as shown in FIG. 2(a), none of LDD regions 26a, 26b provided on the opposite sides of a channel region 22 extends under a gate electrode 24 (LDD structure). In such a TFT, the electric field in the vicinity of source and drain regions 25 can be relaxed by the LDD structure as illustrated in FIG. 2(b). Therefore, the OFF current (OFF leakage current) can be decreased. However, the ON resistance is increased by the LDD regions 26a, 26b, so that the ON current also decreases.

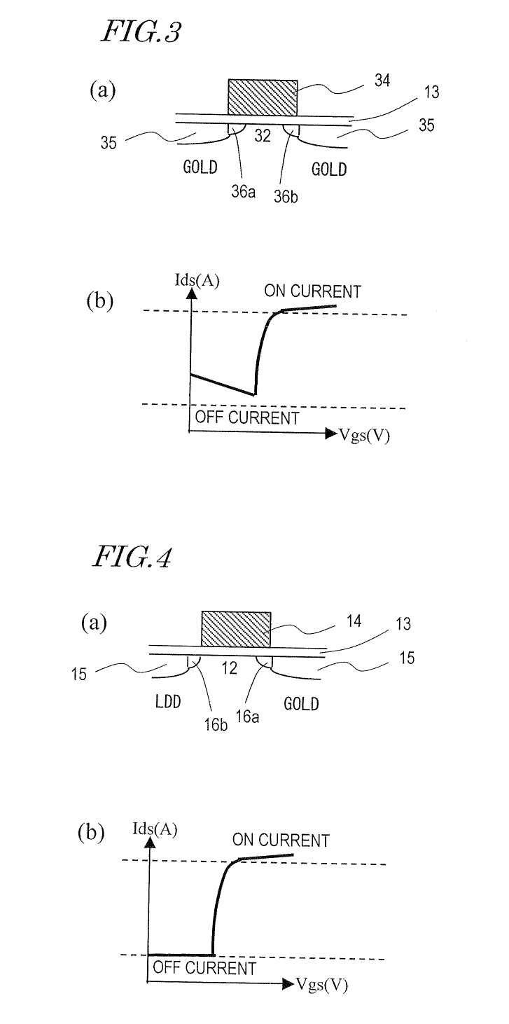

In the conventional GOLD-structure TFT as shown in FIG. 3(a), the entirety of both LDD regions 36a, 36b provided on the opposite sides of a channel region 32 extends under a gate electrode 34 (GOLD structure). Therefore, in the GOLD structure, during the ON state, an accumulation layer is formed in the LDD regions 36a, 36b. Thus, the ON resistance can be reduced as compared with the LDD-structure TFT shown in FIG. 2, so that the ON current can be increased. However, even during the OFF state, the accumulation layer is undesirably formed in the LDD regions 36a, 36b, so that the leakage current increases as compared with the LDD-structure TFT.

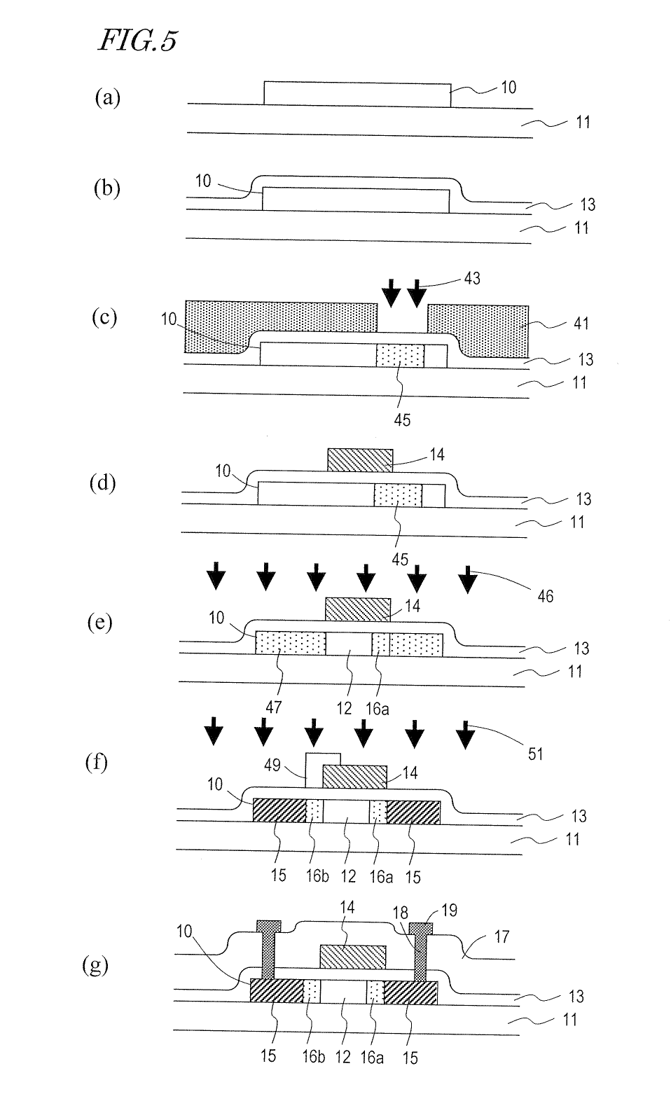

On the other hand, in the thin film transistor 100 as shown in FIG. 4(b), the leakage current during the OFF state can be reduced. Therefore, a higher OFF characteristic can be obtained than in the GOLD-structure TFT shown in FIG. 3. Further, the thin film transistor 100 has the GOLD structure, and therefore, the resistance during the ON state (ON resistance) can be reduced as compared with the LDD-structure TFT shown in FIG. 2. As a result, the reduction of the ON current can be prevented while a high ON characteristic is secured.

In the present embodiment, the gate electrode 14 has a single layer structure. Therefore, the effects of the LDD structure and the GOLD structure can be produced at the same time without increasing the complexity of the fabrication process. Thus, the present embodiment is more advantageous than the above-described TFT structures disclosed in Patent Document 3 and Patent Document 4.

The TFT of the present embodiment can be fabricated using a self-alignment process because the gate electrode does not need to be positioned so as to extend over only part of the LDD regions, whereas it is necessary in the TFT structures disclosed in Patent Document 1 and Patent Document 2. In these patent documents, to more assuredly position the gate electrode so as to extend over only part of the LDD regions, it is necessary to arrange an increased LDD length in view of the alignment accuracy. In the present embodiment, however, the gate electrode may be positioned so as to extend over the entirety of one of the LDD regions and so as not to extend over the other LDD region, and therefore, the LDD length and the TFT size can advantageously be decreased as compared with the TFTs disclosed in these patent documents. In the present embodiment, the LDD length may be decreased to, for example, 1.0 pm or less when the channel length of the thin film transistor 100 is 4.0 pm and the alignment accuracy is 0.5 pm.

In the present embodiment, the gate electrode 14 is preferably parallel to the cross section shown in FIG. 1, i.e., parallel to the channel direction of the thin film transistor 100, and has a symmetric shape in a cross section extending along the thickness direction of the gate electrode 14. This is because, if the gate electrode 14 has an asymmetric shape, application of an electric field becomes unstable, which will be a factor that causes a variation in the TFT characteristics.

In the thin film transistor 100, the LDD regions 16a, 16b are preferably formed using a process which will be described later. By doing so, an end of LDD region (LDD structure) 16b which is opposite to the channel region 12 can be aligned with one end of the gate electrode 14. Also, an end of the LDD region (GOLD structure) 16a on the channel region side can be aligned with the other end of the gate electrode 14. Thus, the fabrication process can be simplified while the thin film transistor 100 having high characteristics can be fabricated more assuredly.

Next, a fabrication method of the thin film transistor 100 is described with reference to FIG. 5(a) to FIG. 5(g).

First, referring to FIG. 5(a), the semiconductor layer 10 is formed on the substrate 11. A surface of the substrate 11 on which the thin film transistor 100 is to be formed may be an insulating surface. The substrate 11 may be a quartz substrate or a glass substrate. Alternatively, it may be a Si substrate or metal substrate whose surface is covered with an insulating layer. The semiconductor layer 10 is constituted of a crystalline silicon film having a thickness of, for example, not less than 30 nm and not more than 100 nm. Specifically, an amorphous silicon film is deposited over the substrate 11 by a known method, such as CVD (Chemical Vapor Deposition) or the like. Thereafter, the amorphous silicon film is crystallized to form the crystalline silicon film. The crystallization of the amorphous silicon film can be carried out using a known method. For example, the amorphous silicon film may be crystallized by irradiating the amorphous silicon film with laser light. The laser light is desirably pulsed excimer laser light or continuous-wave excimer laser light. Alternatively, it may be continuous-wave argon laser light. A catalyst element for enhancing the crystallization, for example, Ni, may be adhered onto the surface of the amorphous silicon film, and then, the amorphous silicon film may be crystallized by a thermal treatment (e.g., laser irradiation). The resultant crystalline silicon film is patterned by photolithography and etching to form the semiconductor layer 10 having the shape of an island. Usually, a plurality of island-shaped semiconductor layers are formed from the above crystalline silicon film. Only one of the island-shaped semiconductor layers 10 is shown herein.

Then, referring to FIG. 5(b), the gate insulating film 13 constituted of a SiO₂ film having a thickness of, for example, 100 nm is formed on the semiconductor layer 10. The formation of the gate insulating film 13 can be carried out using a CVD method.

Then, referring to FIG. 5(c), a resist film 41 is formed over the gate insulating film 13 such that the resist film 41 has an opening extending over part of the semiconductor layer 10 which is to constitute the LDD region 16a (FIG. 1). N-type impurity ion 43 is then implanted at a low concentration via the opening to form an impurity ion implanted region 45. Note that the opening may be positioned over an area that includes the part of the semiconductor layer 10 which is to constitute the LDD region 16a (FIG. 1). As shown, the opening may be positioned over the entirety of the part of the semiconductor layer 10 which is to constitute the LDD region 16a (FIG. 1) and partially over the parts of the semiconductor layer 10 which are to constitute the source and drain regions. Provided that the parts of the semiconductor layer 10 which are to constitute the channel region and the LDD region 16b (FIG. 1) are masked with the resist film 41 such that implantation of the impurity ion 43 is prevented. In the present embodiment, the impurity ion 43 is phosphorus ion, the acceleration voltage for the implantation is for example 80 kV, and the dosage is for example 1×10¹³/cm².

Thereafter, the resist film 41 is removed, and the gate electrode 14 is formed on the semiconductor layer 10 as shown in FIG. 5(d). The gate electrode 14 is positioned so as to cover part of the impurity ion implanted region 45 which is to constitute the LDD region 16a (FIG. 1) and part of the semiconductor layer 10 which is to constitute the channel region. The formation of the gate electrode 14 can be carried out by, for example, forming a tungsten (W) film (thickness: e.g., 400 nm) by sputtering, and thereafter, forming a photoresist over the W film and etching the W film using the photoresist as a mask. Note that the gate electrode 14 may be formed by patterning a layered film constituted of, for example, a TaN film and a W film.

Then, referring to FIG. 5(e), impurity ion 46 is implanted into the semiconductor layer 10 at a low concentration using the gate electrode 14 as a mask. As a result, part of the impurity ion implanted region 45 which is covered with the gate electrode 14 and into which the impurity ion 46 has not been implanted, i.e., a region 16a, constitutes a LDD region (LDD length: e.g., 1.0 pm). Part of the semiconductor layer 10 which is covered with the gate electrode 14 and into which the impurity ion 43 has not been implanted, i.e., a region 12, constitutes a “channel region” (channel length: e.g., 4.0 pm). Part of the semiconductor layer 10 which is opposite to the LDD region 16a relative to the channel region 12 constitutes an impurity ion implanted region 47 that contains the impurity ion 46. In the present embodiment, the impurity ion 46 is phosphorus ion, the acceleration voltage for the implantation is for example 80 kV, and the dosage is for example 6×10¹²/cm².

Thereafter, referring to FIG. 5(f), a resist film 49 is formed so as to cover the gate electrode 14 and part of the semiconductor layer 10 which is to constitute the LDD region 16b (FIG. 1). Impurity ion 51 is implanted at a high concentration in the semiconductor layer 10 using the resist film 49 and the gate electrode 14 as masks. As a result, part of the impurity ion implanted region 47 which is covered with the resist film 49 and into which the impurity ion 51 has not been implanted, i.e., a region 16b, constitutes a LDD region (LDD length: e.g., 1.0 pm). On the outer sides of the LDD regions 16a, 16b, respectively, the impurity ion 51 is implanted at a high concentration to form source and drain regions (or “heavily doped impurity regions”) 15. In the present embodiment, the impurity ion 51 is phosphorus ion, the acceleration voltage for the implantation is for example 50 kV, and the dosage is for example 3×10¹⁵/cm².

After removal of the resist film 49, the impurity ion in the LDD regions 16a, 16b and the source and drain regions 15 are activated by a thermal treatment. A method for the thermal treatment may be furnace annealing, lamp annealing, laser annealing, or the like.

Then, referring to FIG. 5(g), the interlayer insulating film 17 is formed so as to cover the gate electrode 14 and the semiconductor layer 10. Then, the source and drain electrodes 19 is formed. The interlayer insulating film 17 may have a layered structure constituted of a SiN film and a SiO₂ film. After the contact holes 18 are formed in the interlayer insulating film 17, a conductive film is formed by sputtering on the interlayer insulating film 17 (including the inside of the contact holes 18). From this conductive film, the source and drain electrodes 19 having a desired shape is produced by photolithography and etching. In this way, the thin film transistor 100 is obtained.

The semiconductor device of the present embodiment may include a plurality of thin film transistors. At least one of the plurality of thin film transistors may have a structure as shown in FIG. 1. For example, the semiconductor device of the present embodiment may have a structure wherein the above-described thin film transistor 100 and another thin film transistor which has a different structure from that of the thin film transistor 100 are provided on the same supporting body. The another thin film transistor may be, for example, the LDD-structure TFT shown in FIG. 2 or the GOLD-structure TFT shown in FIG. 3. Even such a TFT can be fabricated using a method which is basically the same as that described above by modifying the patterns of the resist film 41 and the resist film 49. Thus, such a TFT and the thin film transistor 100 can be fabricated on the same substrate at the same time.

### Second Embodiment

Hereinafter, the second embodiment of a semiconductor device of the present invention is described with reference to the drawings. The semiconductor device of the present embodiment has a configuration wherein two or more TFTs, including a LDD-structure TFT and a GOLD-structure TFT, are series-connected. Being “series-connected” herein refers to a configuration wherein the source region of a TFT is connected to the drain region of another TFT. Herein, the description is presented with a configuration example where a single LDD-structure TFT and a single GOLD-structure TFT are series-connected (a thin film transistor of a dual gate structure).

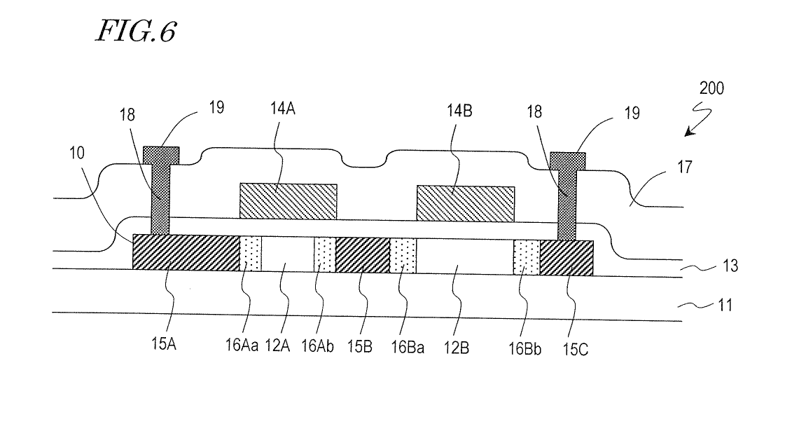

FIG. 6 is a cross-sectional view schematically showing a thin film transistor of the present embodiment. For the sake of simplicity, components that are the same as those of the thin film transistor 100 shown in FIG. 1 are indicated by the same reference numerals, and the descriptions thereof are herein omitted.

The thin film transistor 200 includes a semiconductor layer 10 supported on a substrate 11 that has an insulating surface, a plurality of gate electrodes (herein, two gate electrodes) 14A, 14B which are provided on the semiconductor layer 10 such that a gate insulating film 13 is interposed between the semiconductor layer 10 and the gate electrodes 14A, 14B, and source and drain electrodes 19. The gate electrodes 14A, 14B are interposed between the source and drain electrodes 19.

The semiconductor layer 10 includes two channel regions 12A, 12B, LDD regions 16Aa, 16Ab provided on opposite sides of the channel region 12A, LDD regions 16Ba, 16Bb provided on opposite sides of the channel region 12B, and heavily doped impurity regions 15A to 15C. The heavily doped impurity regions 15A, 15C are provided at opposite ends of the semiconductor layer 10 and are electrically connected to the source and drain electrodes 19, respectively. The heavily doped impurity region 15B is provided between the LDD region 16Ab and the LDD region 16Ba.

The gate electrode 14A is positioned so as to overlap the channel region 12A and the LDD regions 16Aa, 16Ab provided on the opposite sides of the channel region 12A (GOLD structure). On the other hand, the gate electrode 14B is positioned so as to cover only the channel region 12B and so as not to extend over the LDD regions 16B provided on the opposite sides of the channel region 12B (LDD structure).

In a conventional series-connected TFT configuration, TFTs having a structure that is selected according to the use are connected to each other. Specifically, LDD-structure TFTs are connected together, or GOLD-structure TFTs are connected together. The conventional series-connected TFT configuration does not include the concept of connecting TFTs having different structures that are suitable to different uses. On the other hand, in the present embodiment, the LDD-structure TFT and the GOLD-structure TFT are connected together, so that a high ON characteristic can be realized as compared with the series-connected configuration of LDD-structure TFTs, and the OFF leakage current can be reduced as compared with the series-connected configuration of GOLD-structure TFTs.

In the present embodiment, each of the gate electrodes 14A, 14B preferably has a single layer structure as in the first embodiment. Each of the gate electrodes 14A, 14B having a symmetric cross-sectional shape is advantageous.

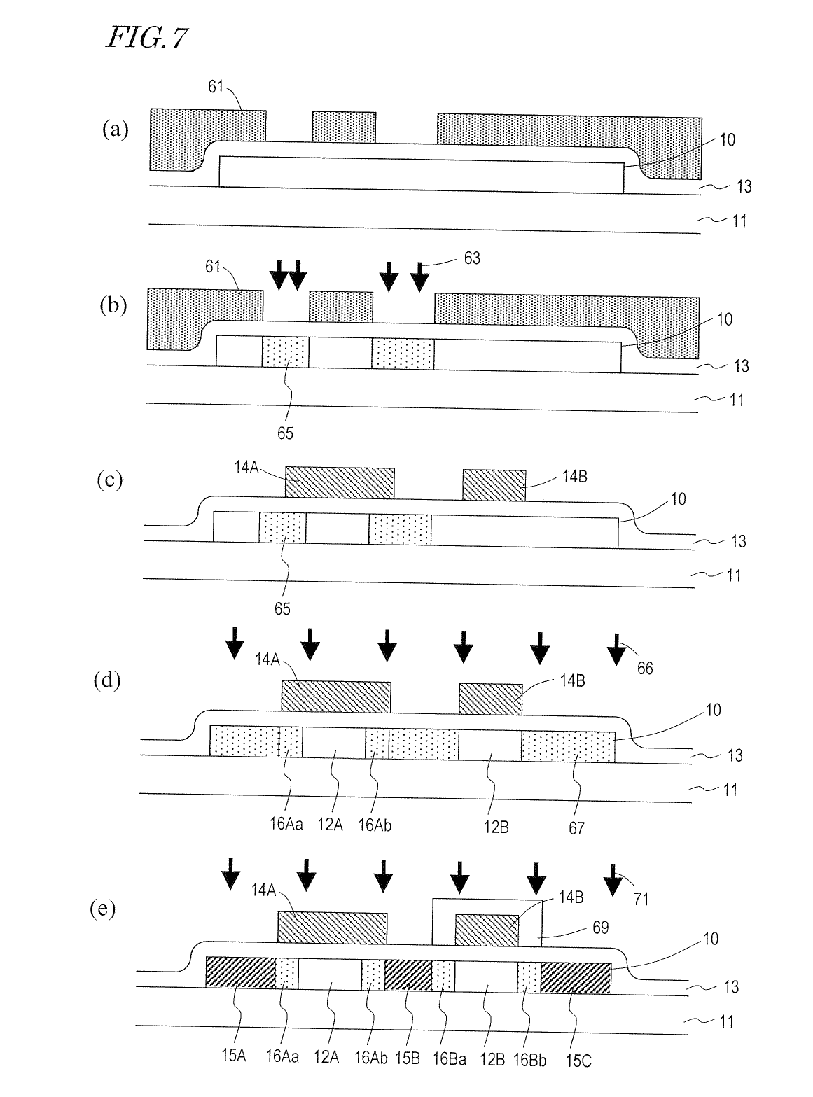

Next, a fabrication method of the thin film transistor 200 shown in FIG. 6 is described with reference to FIG. 7 (a) to FIG. 7(e).

First, the semiconductor layer 10 and the gate insulating film 13 are formed on the substrate 11 by a method which is basically the same as that previously described with reference to FIGS. 5 (a) to 5(b).

Then, referring to FIG. 7(a), a resist film 61 is formed over the gate insulating film 13 such that the resist film 61 has openings over areas including parts of the semiconductor layer 10 which are to constitute the LDD regions 16Aa, 16Ab (FIG. 6). Provided that the resist film is patterned so as to cover at least parts of the semiconductor layer 10 which are to constitute the channel region 12A, the channel region 12B, and the LDD regions 16Ba, 16Bb (FIG. 6).

Then, referring to FIG. 7(b), impurity ion 63 is implanted into the semiconductor layer 10, whereby impurity ion implanted regions 65 are formed. In the present embodiment, the impurity ion 63 is phosphorus ion, the acceleration voltage for the implantation is for example 80 kV, and the dosage is for example 1×10¹³/cm².

Thereafter, the resist film 61 is removed, and the gate electrodes 14A, 14B are formed on the semiconductor layer 10 as shown in FIG. 7(c). The gate electrode 14A is positioned so as to cover parts of the impurity ion implanted regions 65 which are to constitute the LDD regions 16Aa, 16Ab (FIG. 6) and part of the semiconductor layer 10 which is to constitute the channel region 12A (FIG. 6). On the other hand, the gate electrode 14B is positioned so as to cover part of the semiconductor layer 10 which is to constitute the channel region 12B (FIG. 6). The formation method of the gate electrodes 14 may be basically the same as that previously described with reference to FIG. 5(d).

Then, referring to FIG. 7(d), impurity ion 66 is implanted into the semiconductor layer 10 at a low concentration using the gate electrodes 14A, 14B as masks. As a result, parts of the impurity ion implanted region 65 which are covered with the gate electrode 14A and into which the impurity ion 66 has not been implanted, i.e., regions 16Aa, 16Ab, respectively constitute LDD regions (LDD length: e.g., 1.0 gm). Part of the semiconductor layer 10 which extends under the gate electrode 14A and into which both the impurity ion 63 and the impurity ion 66 have been implanted, i.e., a region 12A, constitutes a channel region (channel length: e.g., 4.0 pm). Part of the semiconductor layer 10 which extends under the gate electrode 14B and into which the impurity ion 66 has not been implanted, i.e., a region 12B, constitutes another channel region (channel length: e.g., 4.0 pm). All of parts of the semiconductor layer 10 which do not extend over the gate electrodes 12A, 12B constitute an impurity ion implanted region 67. In the present embodiment, the impurity ion 66 is phosphorus ion, the acceleration voltage for the implantation is for example 80 kV, and the dosage is for example 6×10¹²/cm².

Thereafter, referring to FIG. 7(e), a resist film 69 is formed so as to cover the gate electrode 14B. Impurity ion 71 is implanted at a high concentration in the semiconductor layer 10 using the resist film 69 and the gate electrode 14A as masks. As a result, parts of the impurity ion implanted region 67 which are covered with the resist film 69 and into which the impurity ion 71 has not been implanted, i.e., regions 16Ba, 16Bb, constitute LDD regions (LDD length: e.g., 1.0 pm). Parts of the semiconductor layer 10 into which the impurity ion 71 has been implanted at a high concentration, i.e., regions 15A to 15C, constitute heavily doped impurity regions. Here, the heavily doped impurity region formed on the outer side of the channel region 12A is indicated by “15A”, the heavily doped impurity region formed on the outer side of the channel region 12B is indicated by “15C”, and the heavily doped impurity region formed between the channel regions 12A, 12B is indicated by “15B”. In the present embodiment, the impurity ion 71 is phosphorus ion, the acceleration voltage for the implantation is for example 50 kV, and the dosage is for example 3×10¹⁵/cm².

After removal of the resist film 69, a thermal treatment is performed to activate the impurity ion implanted in the semiconductor layer 10. Thereafter, although not shown, as previously described with reference to FIG. 5(g), the interlayer insulating film 17 is formed so as to cover the gate electrodes 14A, 14B and the semiconductor layer 10, and thereafter, the source and drain electrodes 19 are formed so as to be electrically connected to the heavily doped impurity regions 15A, 15C, respectively. In this way, the thin film transistor 200 of a dual gate structure is obtained.

### Third Embodiment

Hereinafter, the third embodiment of a semiconductor device of the present invention is described with reference to the drawings. The thin film transistor of the present embodiment has a series-connected configuration of two TFTs each of which has the structure previously described with reference to FIG. 1.

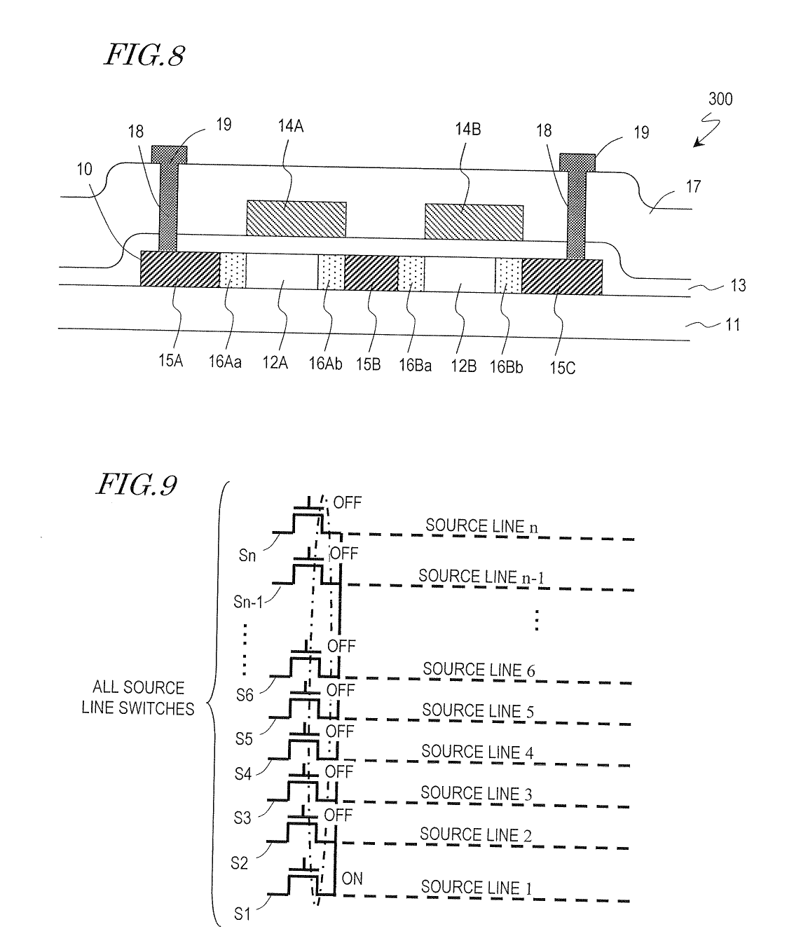

FIG. 8 is a cross-sectional view schematically showing a thin film transistor of the present embodiment. For the sake of simplicity, components that are the same as those of the thin film transistor 200 shown in FIG. 6 are indicated by the same reference numerals, and the descriptions thereof are herein omitted.

In the thin film transistor 300, a gate electrode 14A, which is provided above a channel region 12A, extends over the entirety of one of LDD regions 16Aa, 16Ab that are provided on the opposite sides of the channel region 12A (GOLD structure), and the gate electrode 14A does not extend over the other of the LDD regions 16Aa, 16Ab (LDD structure). Likewise, a gate electrode 14B, which is provided above a channel region 12B, extends over the entirety of one of LDD regions 16Ba, 16Bb that are provided on the opposite sides of the channel region 12B, and the gate electrode 14B does not extend over the other of the LDD regions 16Ba, 16Bb.

According to the present embodiment, as in the first and second embodiments, the ON characteristic can be secured by the GOLD structure, and the OFF leakage current can be reduced by the LDD structure. Thus, a thin film transistor having excellent TFT characteristics can be realized. Further, the thin film transistor 300 of the present embodiment can also be fabricated by basically the same method as that of the first embodiment. Therefore, it is advantageous in that it is not necessary to increase the number of fabrication steps and the fabrication cost as compared with the conventional techniques.

The above-described thin film transistors of the first to third embodiments are suitably used in driving circuits of display devices, and the like. This is advantageous in that the OFF characteristic can be improved as compared with the GOLD-structure TFT while securing a sufficient ON characteristic for driving a circuit.

Using the thin film transistors of the first to third embodiments in sampling switches is particularly advantageous. The reasons therefor are described below with reference to the drawing.

FIG. 9 is a diagram for illustrating a structure of an analog full monolithic sampling switch. As shown, all the source line switches have a plurality of thin film transistors S1 to Sn that are electrically connected to source lines 1 to n, respectively. When a source line is driven, the gate-source capacitances of all the stages of the sampling switches, i.e., the thin film transistors S1 to Sn, constitute the load. Therefore, when the conventional GOLD-structure TFT is used, the load capacitance during operation increases and can adversely affect the circuit operation. On the other hand, when the above-described thin film transistors of the embodiments are used as the thin film transistors S1 to Sn and the LDD region on the source side has the LDD structure, the gate-source capacitance in each of the thin film transistors S1 to Sn becomes small, and as a result, the load capacitance can be greatly decreased. Therefore, the operation margin can be increased, and the current consumption can be reduced.

The above-described thin film transistors of the embodiments are excellent in the ON characteristic and the OFF characteristic as described with reference to FIG. 2 to FIG. 4, and therefore can be preferably used as pixel TFTs of an active matrix display device and also can be preferably used as driving circuit TFTs. Thus, the fabrication process of the active matrix substrate can be greatly simplified while securing the display characteristics generally equal to those of the conventional techniques.

The structure and fabrication method of a semiconductor device of the present invention are not limited to those described in the first to third embodiments. The formation method, materials, thickness, and impurity type of respective layers of the thin film transistor, and the impurity concentration in respective LDD regions, can be appropriately selected. The channel length of the thin film transistor and the size of the LDD region (the length along the channel direction) can also be appropriately selected. Although in the second and third embodiments the series-connected configurations of two TFTs have been described, it may be a series-connected configuration of three or more TFTs.

### INDUSTRIAL APPLICABILITY

A thin film transistor of the present invention has improved current drivability as compared with a conventional thin film transistor having a LDD structure. Further, the OFF leakage current can be reduced, while the load capacitance during operation can be reduced, as compared with a conventional thin film transistor having a GOLD structure. According to a method of the present invention, a semiconductor device which includes the above-described thin film transistor can be conveniently manufactured without increasing the number of steps.

The present invention is preferably applicable to a wide variety of semiconductor devices which include thin film transistors, for example, active matrix substrates, and display devices, such as liquid crystal display devices, organic EL display devices, etc.

1.-3. (canceled)

4. A semiconductor device comprising a thin film transistor, the thin film transistor including a semiconductor layer which includes first and second channel regions, a first heavily doped impurity region provided on an outer side of the first channel region, a second heavily doped impurity region provided on an outer side of the second channel region, and a third heavily doped impurity region provided between the first and second channel regions,
a gate insulating layer provided on the semiconductor layer,
first and second gate electrodes which are provided on the gate insulating layer and which are provided over the first and second channel regions, respectively,
a first electrode electrically connected to the first heavily doped impurity region, and
a second electrode electrically connected to the second heavily doped impurity region,
wherein the semiconductor layer further includes
first lightly doped impurity regions provided between the first channel region and the first heavily doped impurity region and between the first channel region and the third heavily doped impurity region, the first lightly doped impurity regions having a lower impurity concentration than those of the first, second, and third heavily doped impurity regions, and
second lightly doped impurity regions provided between the second channel region and the second heavily doped impurity region and between the second channel region and the third heavily doped impurity region, the second lightly doped impurity regions having a lower impurity concentration than those of the first, second, and third heavily doped impurity regions, and an entirety of each of the first lightly doped impurity regions extends under the first gate electrode, and the second lightly doped impurity regions do not extend under the second gate electrode.

5. The semiconductor device of claim 4, wherein the first and second gate electrodes are constituted of a single conductive film.

6. The semiconductor device of claim 4, or 5, wherein the first and second gate electrodes have a symmetric shape in a cross section which is parallel to a channel direction of the thin film transistor and which extends along a thickness direction of the gate electrodes.

7. (canceled)
